(19) United States
(12) Patent Application Publication
(10) Pub. No.: US 2011/0248797 A1
(43) Pub. Date: Oct. 13, 2011

(54) TUNABLE DELAY SYSTEM AND CORRESPONDING METHOD

(76) Inventors: Christophe Caloz, Montreal (CA); Van-Hoang Nguyen, Montreal (CA); Samer Abielmona, Ottawa (CA); Shulabh Gupta, Montreal (CA)

(21) Appl. No.: 12/532,359

(22) PCT Filed: Mar. 18, 2008
(86) PCT No.: PCT/CA2008/000516

§ 371 Date: Jun. 3, 2011

Related U.S. Application Data
(60) Provisional application No. 60/896,591, filed on Mar. 23, 2007.

(51) Int. Cl. H03H 7/18

(52) U.S. Cl. 333/139

(57) ABSTRACT

The present invention relates to a tunable delay system and corresponding method for delaying a signal. The system includes an oscillator for providing a carrier. A first mixer modulates the signal with the carrier. The modulated signal is delayed in a metamaterial transmission line. Afterwards, a second mixer is used to separate the delayed signal from the carrier. The present invention also relates to using a metamaterial transmission line for delaying a modulated signal.

### FIELD OF THE INVENTION

The present invention relates to a tunable delay system and corresponding method, and more particularly to a tunable delay system and method using metamaterial technology.

### BACKGROUND OF THE INVENTION

There are various ways to achieve time delays, where a simple transmission line is the simplest form of a delay line. For tunable delays, a few implementation approaches are available, from using varactor diodes loaded on a transmission line, to surface acoustic wave (SAW) and magneto-static wave (MSW) devices. Yet, all three approaches display an intrinsic disadvantage when operated in microwave circuits.

A transmission line loaded with tunable varactors exhibits a variation in its characteristic impedance, dependent on the varactor value, as described in article titled “Novel low-loss delay line for broadband phased antenna array applications,” by authors W.-M. Zhang, R. P. Hsia, C. Liang, G. Song, C. W. Domier, and N. C. Jr. Luhmann, published in Microwave and Guided Wave Lett., Vol. 6, No. 11, November 1996, pp. 395-397. In turn, this naturally leads to a mismatching effect between the transmission line and its surrounding circuitry, leading to deterioration in performance over a broad band.

On the other hand, time delays in surface acoustic wave (SAW) and magneto-static wave (MSW) devices are attained without altering their characteristics, hence removing the mismatch impediment. However, as described in article titled “A continuously variable delay-line system,” by authors V. S. Dolat, and R. C. Williamson, and published in 1976 Proc. IEEE Ultrasonics Symposium., pp. 419-423, SAW devices are limited in terms of operational frequency and bandwidth constrained to only several MHz, while MSW devices utilize a bulky magnet requiring accurate mechanical alignment, not conducive for planar microwave circuits. More information on MSW devices can also be found in a book titled “Thin Films for Electronic Devices, by M. H. Francombe and J. L. Vossen.

There is therefore a need for a tunable delay system, which overcomes the aforementioned drawbacks of conventionally delay lines and devices.

### SUMMARY OF THE INVENTION

The present invention provides a tunable delay system and method, suitable for continuous wave and impulse wave signals, and for wide ranges of frequencies and applications.

For doing so, the present invention provides a tunable delay system for delaying a signal. The system includes an oscillator, a first and second mixers, and a metamaterial transmission line. The oscillator is adapted for providing a carrier. The first mixer modulates the carrier with the signal. The modulated signal is then delayed using the metamaterial transmission line. Finally, the second mixer is adapted for separating the delayed signal from the delayed carrier.

In accordance with another aspect, the present invention relates to a method for delaying a signal. The method includes a step for modulating the signal with a carrier. Then, the method proceeds with a step of delaying the modulated signal using a metamaterial transmission line. Finally, the method continues with separating the delayed signal from the delayed carrier.

### BRIEF DESCRIPTION OF THE DRAWINGS

In the following description, the following drawings are used to describe and exemplify the present invention:

FIG. 1 is a schematic representation of a tunable delay system in accordance with a first aspect of the present invention, along with graphical representation of continuous and impulse delayed signals;

FIG. 2 is a graphical representation of measured S₁₁ and S₂₂ for a 30-unit cell Composite Right/Left-Handed Transmission Line (CRLH TL), using a transition frequency ωₒ=2.55 GHz, in accordance with an aspect of the present invention;

FIG. 3 is a system prototype showing a 30-unit cell CRLH delay line system in accordance with another aspect of the invention;

FIG. 4 is graphical representation of time delayed waveforms for different carrier frequencies (experimental and circuit) for an impulse wave and a continuous wave;

FIG. 5 is a graphic depicting comparison between theoretical, simulated, and measured delays for continuous and pulse waveforms at various carrier frequencies; and

FIG. 6 is a schematic representation of a Pulse Position Modulation Ultra Wide Band transmitter in which the tunable delay system of the present invention is incorporated.

### DETAILED DESCRIPTION OF THE INVENTION

The present invention relates to a tunable delay system and corresponding method. This tunable delay system, which incorporates a metamaterial transmission line, achieves a tunable group delay for impulse and continuous-wave signals, controlled by a local oscillator. This group delay's tunability follows from dispersion properties of the metamaterial transmission line, and can be achieved without suffering from drawbacks of conventional delay lines in terms of matching, frequency of operation, and planar circuit implementation. A proof-of-concept prototype, included further, exhibits measured group delays tunable between 5:1 ns and 8:54 ns, over a frequency range of 2-4:5 GHz. Due to the achieved performances, the present tunable delay system can be used for several applications in various types of systems such as for example broadband systems.

Delay lines are ubiquitously employed in various microwave devices and subsystems. Mainly used as time delayers or phase shifters, they find application in phased arrays, feed-forward amplifiers, delay-lock loops, phase noise measurement systems, and oscillators.

The present invention relies on metamaterial, and consists of composite right/left-handed (CRLH) transmission line (TL). This new TL offers a new Radio Frequency paradigm, and leads to many novel components, antenna and quasi-optical concepts and applications. The concept of metamaterial is described in references, such as:
C. Caloz and T. Itoh, Electromagnetic Metamaterials, Transmission Line Theory and Microwave Applications, Wiley and IEEE Press, 2005.
United States Patent Application Number 20060066422, titled “Zeroeth-order resonato”, published Mar. 30, 2006; and
United States Patent Application Number 20050253667, titled “Composite right/left handed couplers”, published Nov. 17, 2005.
Throughout the present specification, the expressions “metamaterial” and “CRLH delay line” are alternatively used. The expression “metamaterial” is used to refer to electromagnetic metamaterials (MTMs), which are broadly defined as artificial effectively homogeneous electromagnetic structures with unusual properties not readily available in nature.

Thus, in an aspect of the present invention, the tunable delay system of the present invention consists of a carrier frequency tunable impulse/continuous wave (also called harmonic wave) CRLH delay line system, which, by combining the dispersive properties of CRLH structures with a modulated delay system, provides unprecedented features in terms of frequency operation, bandwidth, simplicity, and design flexibility.

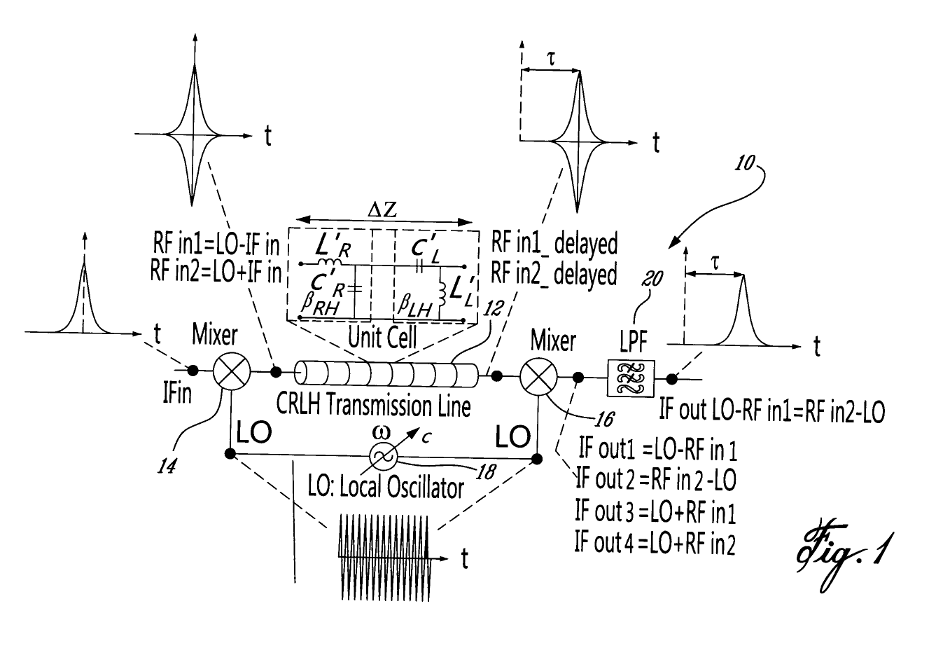

As shown in FIG. 1, the CRLH TL is an artificial TL constructed of cascaded unit cells, composed of capacitors and inductors. Operated in a balanced mode, the CRLH TL can be considered as the combination of a Right-Handed (RH) and Left-Handed (LH) TLs, with a gapless transmission pass-band and broadband matching. Propagation constant of a balanced (equal impedance and admittance resonance frequencies) of the CRLH line is given as

$$β ( ω ) = p ( \frac{ω}{{ω}_{R}} - \frac{{ω}_{L}}{ω} ) , \qquad ( 1 )$$

where ω_{R}=1/\sqrt{L_{R}C_{R}}, ω_{L}=1/\sqrt{L_{L}C_{L}} and p is the size of the unit cell. The RH and LH contributions of the CRLH TL are manifested in the first and second term of Equation (1), respectively, representing a simple delay in time (linear phase term) and distortion (hyperbolic phase term), respectively. Thus, considering a signal of restricted bandwidth Δω centered at a frequency ω_{c}, with the condition Δω<<ω_{C}, the resulting group delay in a balanced CRLH TL is given as the derivative of Equation (1) at ω_{C} or

$${τ}_{g} ( {ω}_{C} ) = N [ \frac{1}{{ω}_{R}} - \frac{{ω}_{L}}{{ω}_{C}^{2}} ] , \qquad ( 2 )$$

where N represents a number of unit cells in the CRLH TL. The center frequency ω_{C} represents the frequency of a carrier modulating the signal of bandwidth Δω. From Equation (2), it can be appreciated that the group delay is dependent on the carrier frequency. Thus, by varying ω_{C}, the delay of the signal can be tuned accordingly, with a negative slope corresponding to anomalous dispersion of the CRLH TL, as demonstrated by Equation (3).

$$\frac{\partial {τ}_{g}}{\partial ω} = \frac{2 N {ω}_{L}}{{ω}_{C}^{3}} < 0 , \qquad ( 3 )$$

Thus, the number of unit cells, the frequency ω_{c} and the restricted bandwidth Δω can be varied so as to obtain different characteristics for the TL.

Again referring to FIG. 1, components of the tunable delay system of the present invention are depicted. The tunable delay system 10 consists of the composite right/left-handed (CRLH) transmission line (TL) 12, a first and second mixers, respectively 14 and 16, an oscillator 18 and a low-pass filter 20. The oscillator 18 is adapted for providing the carrier frequency ω_{c}. The first mixer 14 is adapted for modulating the carrier frequency with the signal to be delayed. Then, the CRLH transmission line 12 delays the modulated signal. The delayed modulated signal is then fed into the second mixer 16, which role is to separate the delayed signal from the delayed carrier frequency. Finally, to remove harmonics of the carrier frequency and further improve quality of the delayed signal, the delayed signal is further passed through the low-pass filter 20. As the oscillator 18 provides the carrier frequency, and as the carrier frequency allows tuning the delay achieved by the tunable delay system 10, it can be appreciated that the oscillator 18 further acts as a tuning mechanism.

Because of its flexibility, the tunable delay system 10 and the composite right/left-handed transmission line 12 are adapted to delay various types of signals, including ultra-wideband signals.

More precisely, in the first mixer 14, the input signal (continuous wave or pulse), of center frequency IFᵢₙ, is modulated with a variable carrier frequency from the voltage-controlled oscillator 18 of frequency LO, leading to a modulated signal with the two frequencies RFᵢₙ₁=LO−IFᵢₙ and RFᵢₙ₂=LO+IFᵢₙ. The modulated signal is then passed through the CRLH TL 12, demodulated in the second mixer 16 to yield the four output frequencies IFₒᵤₜ₁=LO−RFᵢₙ₁, IFₒᵤₜ₂=RFᵢₙ₂−LO, IFₒᵤₜ₃=LO+RFᵢₙ₁ and IFₒᵤₜ₄=LO+RFᵢₙ₂, and finally passed though the low-pass filter 20 to remove the modulation frequency and restore the input signal of center frequency IFₒᵤₜ₃=LO−RFᵢₙ₁=RFᵢₙ₂−LO. In this process, the input signal has been delayed in time by τ according to Eqs. (2) and (3), which is controlled by the carrier frequency of the LO, ω_{C}.

An experiment has been conducted to validate the potential and achievable results of the present tunable delay system 10. For doing so, a 30-unit cells CRLH TL 12 has been implemented using metal-insulator-metal technology for capacitors and shorted stubs for inductors. Such technology is described in a publication titled “Simple-design and compact MIM CRLH microstrip 3-dB coupled-line coupler,” by H. V. Nguyen, and C. Caloz Proc. in IEEE MTT-S Int. Microwave Symposium. Digest, June 2006, pp. 1733-1736.

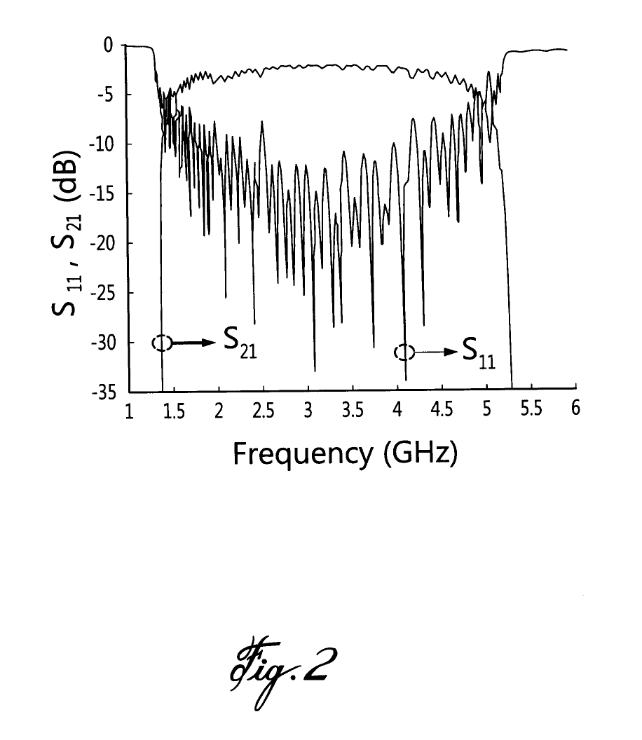

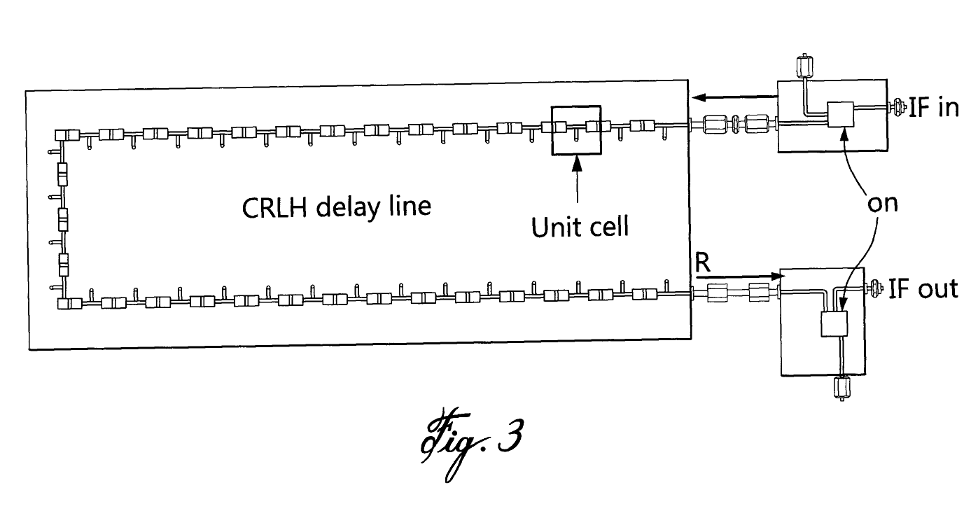

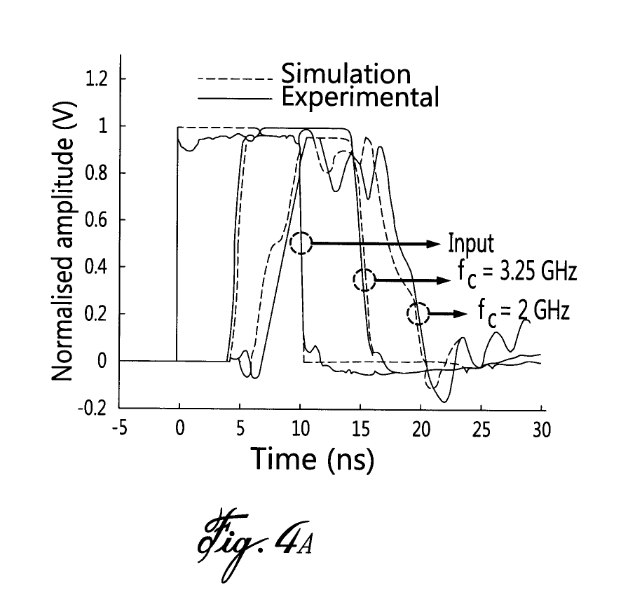

Reference is now made concurrently to FIGS. 1 and 2, wherein FIG. 2 depicts a graphical representation of measured S₁₁ and S₂₂ for the 30-unit cell CRLH TL of the conducted experiment, using a transition frequency ωₒ=2.55 GHz. For conducting the experiment, commercial mixers were chosen with an IF range of 0.1-1.5 GHz, able to handle narrow pulses, and LO and RF ranges of 1-5 GHz, with acceptable isolation between all ports. The tunable delay system prototype used to conduct the experiment is shown in FIG. 3. The CRLH equivalent circuit model parameters used were L_{R}=4.2 nH, C_{R}=2.1 pF, L_{L}=2 nH, C_{L}=0.95 pF.

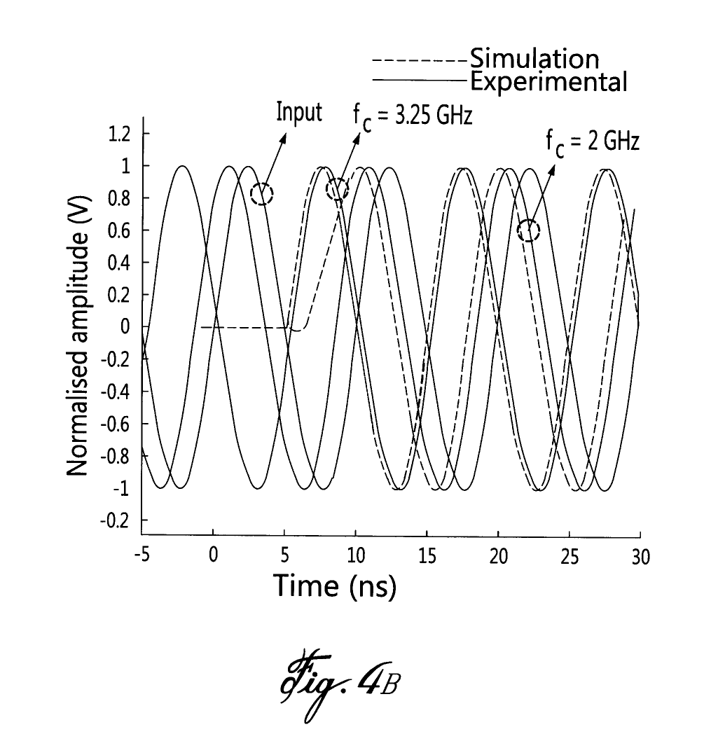

The prototype shown on FIG. 3 was tested to experimentally characterize the achievable delays. FIG. 4(a) shows both measured input and delayed output impulse waveforms, along with their corresponding circuit simulation waveforms using equivalent model values of FIG. 3. Similarly, FIG. 4(b) shows measured and simulated results for a continuous waveform signal.

In FIG. 4(a), the delayed output impulse experiences more distortion at lower frequencies due to the more significant CRLH dispersion. Thus, the time delays of an impulse are measured as a mean value of rise, center, and fall times. The measured time delays at 2 GHz were 8.13 ns and 8.54 ns for impulse and continuous wave, respectively, while at 3.25 GHz, the measured delays were 5.36 ns and 5.39 ns, respectively. As can be seen, the measured and simulated delays closely agree with each other for impulse and continuous signals.

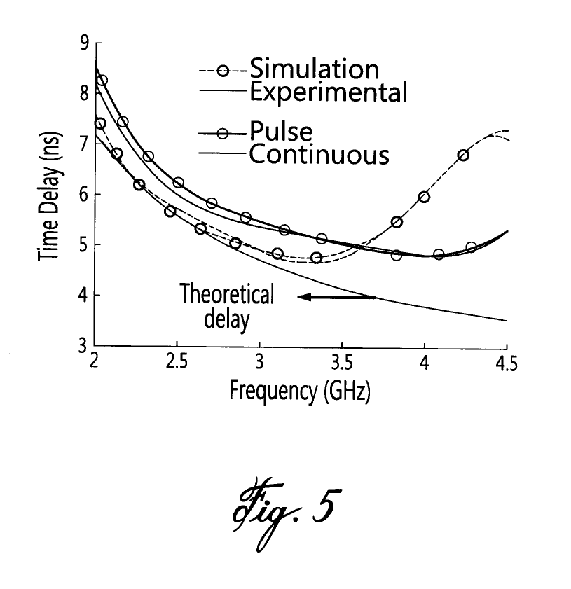

Reference is now made to FIG. 5, which depicts measured and simulated time delays for impulse and continuous wave signals at various carrier frequencies within the CRLH TL pass-band. The simulation results closely follow the theoretical results of Equation (2). The tuning sensitivity ∂r_{g}/∂ω, as predicted by Equation (3), is more pronounced at lower frequencies, due to a slow-wave compression occurring in the left-handed band of the CRLH transmission line. In addition, with increasing carrier frequency up to 3.5 GHz, both the simulated and experimental delays decrease similarly, as predicted by Equations (2) and (3), with a small discrepancy between simulation and measurement. However, above 3.5 GHz, the delay increases due to the stop-band proximity, where v_{g}=0 and τ_{g}=∞. A smaller increase is observed in the experimental delays, where an imperfect circuit simulation model was used for comparison having a lower right-hand cut-off frequency.

It will be apparent to those skilled in the art that the proposed CRLH delay system can be further improved and applied to various broadband systems. For such applications, the current distortion of highly delayed pulses, shown on FIG. 4a, due to corresponding high dispersion could be suppressed or at least mitigated. Such suppression could be necessary in applications requiring important delays. For doing so, two possibilities are possible: a) a second transmission line of opposite dispersion (i.e. normal dispersion since the CRLH transmission line exhibits anomalous dispersion) connected to the output of the CRLH transmission line before the second mixer; b) alternatively, a positively-chirped local oscillator (repetitive linear frequency ramps in time) inserted at the same location to also compensate for the dispersion.

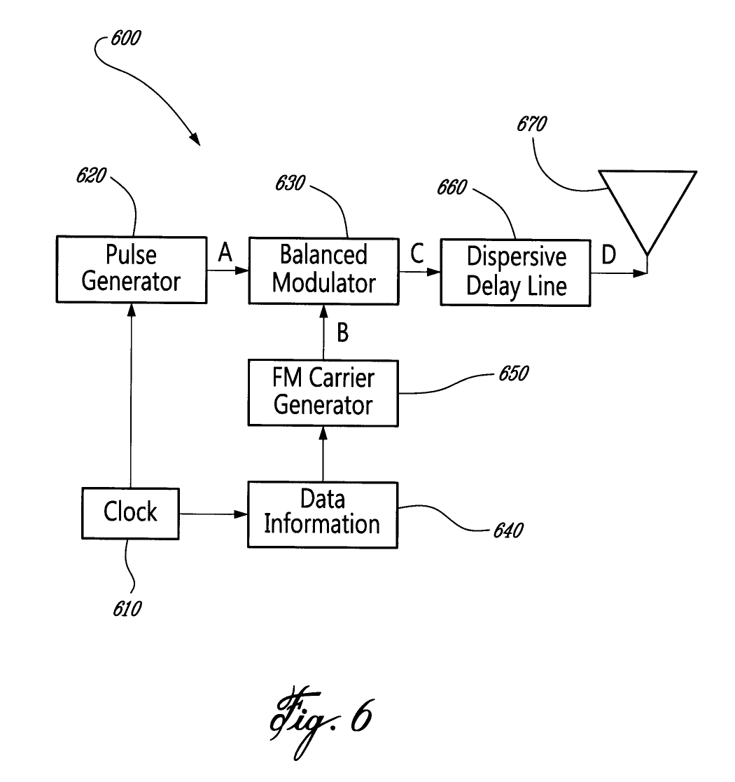

Another application of the CRLH delay system of the present invention is to pulse position modulation (PPM) transmitter for impulse Ultra Wide Band (UWB) data transmission. An example of such a PPM transmitter is shown on FIG. 6, the PPM transmitter includes a clock 610, a pulse generator 620, a balanced modulator 630, a data information 640, an FM carrier generator 650, a dispersive delay line 660 and an antenna 670.

The balanced modulator 630 modulates a Gaussian pulse signal generated by the pulse generator 610 with a carrier frequency generated by the FM carrier generator 650. The carrier generator 650 is capable of generating two distinct carrier frequencies: f₀ for data bit “0” and f₁ for data bit “1”. Depending on these carrier frequencies, the modulated Gaussian pulse signals have different time delay for bit “0” and “1”. The different time delay of the binary data bit is the basic of the pulse modulation. The time delay can be conveniently tuned by varying the carrier frequencies of bit “0” and “1”. Then, the time-delayed, frequency modulated Gaussian signals are transmitted by the wideband antenna 670. In this application, the CRLH dispersive delay line 660 accurately controls the position of and the delay of transmitted pulses in time. This embodiment of PPM transmitter thus provides a simple, passive and effective pulse position modulator suitable for Ultra Wide Band wireless communications.

The present invention can further be used for various applications, such as compressive devices. Examples of such applications include frequency discriminators for phase noise measurement, compressive receiver for radar, tunable delay line for feed-forward amplifiers, phased array feeding networks, tunable delay lines for oscillators, and pulse position modulators for ultra-wideband.

The tunable delay system of the present invention thus offers several advantages over conventional systems where it is wideband with good matching, operational at high frequency, and is suitable for any planar circuit implementation technology. In addition, it offers variable tuning delay without changing the characteristics of the dispersive medium, and preserving good matching throughout the tuning band.

In accordance with another aspect, the present invention provides a method for delaying a signal. The method includes steps of modulating the signal with a carrier, delaying the modulated signal using a metamaterial transmission line, and separating the delayed signal from the delayed carrier.

The present invention has been described by way of preferred embodiments. It should be clear to those skilled in the art that the described preferred embodiments are for exemplary purposes only, and should not be interpreted as limiting the scope of the present invention. The tunable delay system and method as described in the description of preferred embodiments can be modified without departing from the scope of the present invention. The scope of the present invention should be defined by reference to the appended claims, which clearly delimit the protection sought.

1. A tunable delay system for delaying a signal, the system comprising:
an oscillator for providing a carrier;
a first mixer for modulating the carrier with the signal;
a metamaterial transmission line for delaying the modulated signal; and
a second mixer for separating the delayed signal from the delayed carrier.

2. The tunable delay system of claim 1, wherein the metamaterial transmission line is a composite right/left-handed transmission line.

3. The tunable delay system of claim 1, wherein a delay applied by the metamaterial transmission line delays to the mixed carrier and signal is a function of a frequency of the carrier.

4. The tunable delay system of claim 3, further comprising a tuning mechanism for adjusting the frequency of the carrier so as to tunably delay the signal.

5. The tunable delay system of claim 2, wherein the composite right/left-handed transmission line is an artificial transmission line including cascaded unit cells composed of capacitors and inductors.

6. The tunable delay system of claim 5, wherein dispersion properties of the composite right/left handed transmission line are used for delaying the modulated signal.

7. The tunable delay system of claim 6, wherein the composite right/left-handed transmission line is adapted to delay a modulated pulsed signal.

8. The tunable delay system of claim 6, wherein the composite right/left-handed transmission line is adapted to delay a modulated harmonic signal.

9. The tunable delay system of claim 6, wherein the composite right/left-handed transmission line is adapted to delay a modulated ultra-wideband signal.

10. Use of the tunable delay system of claim 1 in an Ultra Wide Band transmitter relying on pulse position modulation.

11. A method for delaying a signal, the method comprising steps of:
modulating the signal with a carrier;
delaying the modulated signal using a metamaterial transmission line; and
separating the delayed signal from the delayed carrier.

12. The method of claim 10, wherein the metamaterial transmission line is a composite right/left-handed transmission line.

13. The method of claim 10, wherein the delaying is a function of a frequency of the carrier.

14. The method of claim 12, further comprising a step of tuning the delaying of the modulated signal by adjusting the frequency of the carrier.

15. The method of claim 11, wherein the composite right/left-handed transmission line is an artificial transmission line including cascaded unit cells composed of capacitors and inductors.

16. The method of claim 14, wherein dispersion properties of the composite right/left handed transmission line are used for delaying the modulated signal.

17. The method of claim 15, wherein the composite right/left-handed transmission line is adapted to delay a modulated pulsed signal.

18. The method of claim 6, wherein the composite right/left-handed transmission line is adapted to delay a modulated harmonic signal.

19. The method of claim 15, wherein the composite right/left-handed transmission line is adapted to delay a modulated ultra-wideband signal.

20. Use of dispersive properties of a metamaterial transmission line for delaying a modulated signal.
